(19) United States
(12) Patent Application Publication
(10) Pub. No.: US 2006/0134457 A1
(43) Pub. Date: Jun. 22, 2006

(54) Method of preparing organic luminescent materials stabilized by heat treatment and meaterials thus obtained

(76) Inventors: Giuseppe Baldacchini, Frascati (IT); Angelo Pace, Frascati (IT); Tommaso Baldacchini, Grotalerrola (IT); Ramchandra Balaji Pode, Nagpur (IT)

Correspondence Address: NIXON & VANDERHYE, PC, 901 NORTH GLEBE ROAD, 11TH FLOOR, ARLINGTON, VA, 22203, US

(21) Appl. No.: 10/530,727

(22) PCT Filed: Sep. 19, 2003
(86) PCT No.: PCT/IT03/00555

§ 371 Date: Nov. 3, 2005

(30) Foreign Application Priority Data
Oct. 10, 2002 (IT) RM2002A000513

(51) Int. Cl. H01L 51/56; C09K 11/06; H01L 51/52

(52) U.S. Cl. 428/690; 427/66; 252/301.16; 428/917; 313/504; 313/512; 257/100; 257/E51.02

(57) ABSTRACT

The present invention relates to methods of preparing and stabilizing organic luminescent materials by means of heat treatment (annealing) in a suitable atmosphere. The treatment performed on films of such materials deposited on an inert support causes an immediate increase of the luminescence and a stabilization of the emission in ambient atmosphere for at least 500 hours.

### TECHNICAL FIELD OF THE INVENTION

The present invention relates to methods of preparing stabilized luminescent organic materials, methods of stabilizing the luminescence of organic substances, materials obtained by means of said methods and devices (OLEDs or Organic Light Emitting Devices) and articles comprising such materials.

### PRIOR STATE OF THE ART

Over the last decade, organic compounds attracted the attention of the scientific and technological community as luminescent materials having efficiencies comparable to those of the well-known inorganic materials, such as the semiconductors and the insulating solids used to date for the preparation of LEDs (Light Emitting Diodes). In particular, organic compounds have been used in the field of electroluminescence, i.e. an electric current flow induced emission, with results so momentous that at present several optoelectronic devices have been made with these materials in lieu of the usual semiconducting diodes (J. R. Sheats, H. Antoniadis, M Hueschen, W. Leonard. J. Miller, R. Moon, D. Roitman, and A. Stoking, Science, 273, 884-888 (1996); M. J. Felton, Today's Chemist at Work, 31-34, November 2001). The reason of this success lies in that the organic materials, besides possessing a high luminescent efficiency, a prerequisite for all luminescent materials, require elementary basic technology for their preparation and the cost of the material is negligible. However, aside from several advantages these materials entail some drawbacks restricting their applicative use. Without going into the details of their operation it is well-known that their luminescent efficiency decreases over time, under electrical excitation as well as owing to effects due to atmospheric moisture and oxygen (F. Papadimitrakopoulos, X. -M. Zhang, Synthetic Met. 85, 1221-1224 (1997); M. Schaer, F. Nuesch. D. Berner, W. Leo, and L. Zuppiroli, Adv. Funct. Mater. 11, 116-121 (2001)). In fact, a device unprotected from atmosphere has an average life of 1-10 hours, whereas the same device suitably encapsulated has an average life of about 5000 hours. However, this life, which in some cases has been exceeded of a x2 or x3 factor, is not yet deemed sufficient to justify a generalized applicative use of these molecules (M. J. Felton et al supra). Moreover, it should be mentioned that any encapsulation falls short of perfectly sealing the device over an arbitrarily long time, and moreover cannot prevent a lengthy yet inescapable internal degassing process.

A method of stabilizing organic luminescent substances is disclosed in Intl. Pat. Appln. PCT/IT02/00504 to ENEA. This prior method foresees the use of compounds of phenolic origin preventing degradation of the organic luminescent materials and prolonging luminescence duration.

Moreover, it is known that a heat treatment (annealing) on a film of photoluminescent material causes a certain stabilization of the luminescent emission with regard to hydrolysis, however at the expense of the emission efficiency (F. Papadimitrakopoulos, X. -M. Zhang, and K. A. Higginson, IEEE J. of Selected Topics in Quant. Electron. 4. 49 (1998)). These prior methods already provide a remarkable improvement of the luminescence efficiency. Yet, there subsists the demand for materials characterized by an even greater emission intensity and an even longer half-life (luminous efficiency halving time) and enabling a generalized practical application.

Hence, scope of the invention is to meet this demand.

In particular, scope of the invention is to produce luminescent materials having a high efficiency and an half-life longer than that of prior art materials.

### SUMMARY OF THE INVENTION

The invention is based on the unforeseen finding that the luminescence of specific organic substances can effectively be increased and stabilized via a heat treatment (annealing) in an atmosphere having variable moisture contents at a predetermined temperature and controlled experimental conditions.

In particular, the method according to the invention enables to markedly increase the emissive power of organic substances deposited in thin film on a solid support. This increased efficiency is the sum of two advantageous and totally unexpected effects, specifically: a net immediate increase of the luminescent emission intensity of the film, even for a film freshly-prepared and therefore of already good luminescence, and, even more significantly, a near-constant holding of the emission intensity on maximum values for at least 500 hours in the absence of any kind of protection: a result never observed before.

Hence, the main object of the invention is a method of preparing an organic material capable of emitting luminescence comprising the steps of: depositing a thin film of organic luminescent substance on an inert solid support, then annealing the substance in a humidified or anhydrous atmosphere at a predetermined temperature and for suitable periods of time, and returning to room temperature in the same atmosphere the thus treated substance in the shortest possible time, anyhow not longer than 5 min. The heat treatment is conducted at a temperature ranging from 120 to 180° C. in an atmosphere of air, oxygen, nitrogen or any other inert gas or mixture thereof containing different moisture levels. Advantageously, the organic substance used is a fluorescent substance like Alq₃ or its derivatives, or equivalent substances, alone or in a mixture.

A second object of the invention is a method of stabilizing the luminescence of luminescent substances, comprising the step of annealing the substance in a humidified or anhydrous atmosphere at a predetermined temperature and for suitable periods of time, and returning to room temperature the substance thus treated in the shortest possible time, anyhow not longer than 5 min, in the same atmosphere.

Further objects of the invention are the above methods of preparing and stabilizing comprising further forms of luminescence stabilization, like the use of phenolic substances in a mixture with the organic luminescent substances.

Other objects of the invention are the organic materials obtained by means of the disclosed method, having stabilized luminescence, films made of said materials on an inert support, devices incorporating said films and optionally encapsulated in moisture- and external gas-proof systems.

Other objects of the invention will become apparent in the light of the detailed description.

### BRIEF DESCRIPTION OF THE FIGURES

FIGS. 1, 4, 5, 6, 7, 12, 13, 14, 15 and 16 reproduce graphs in which the normalized intensity of the luminescent emission (y axis) is reported as a function of time (x axis).

FIGS. 2 and 3 reproduce graphs in which the normalized intensity of the luminescent emission in arbitrary units (y axis) is shown as a function of temperature (x axis).

FIGS. 8, 9, 10 and 11 reproduce graphs in which the intensity of the luminescent emission in arbitrary units (y axis) is shown as a function of the emission wavelength (x axis).

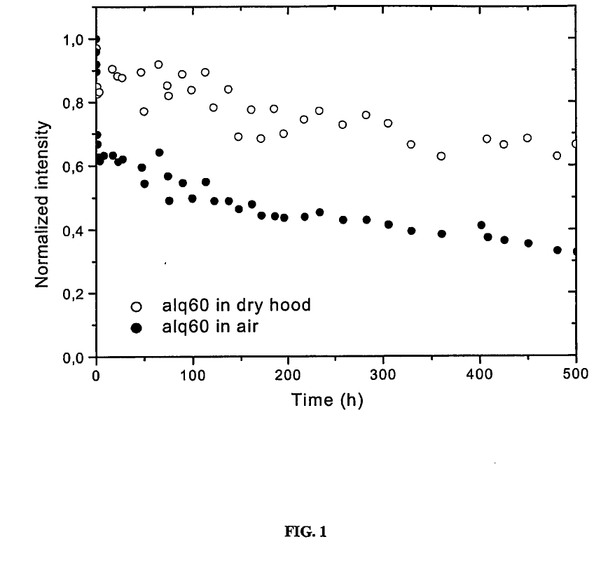

FIG. 1. The figure illustrates the photoluminescence at room temperature of two films of Alq₃, controlled for 500 hours in air (dark circles) and in a dry hood (light circles) after the evaporation process. The Alq60 sample is 140 nm thick.

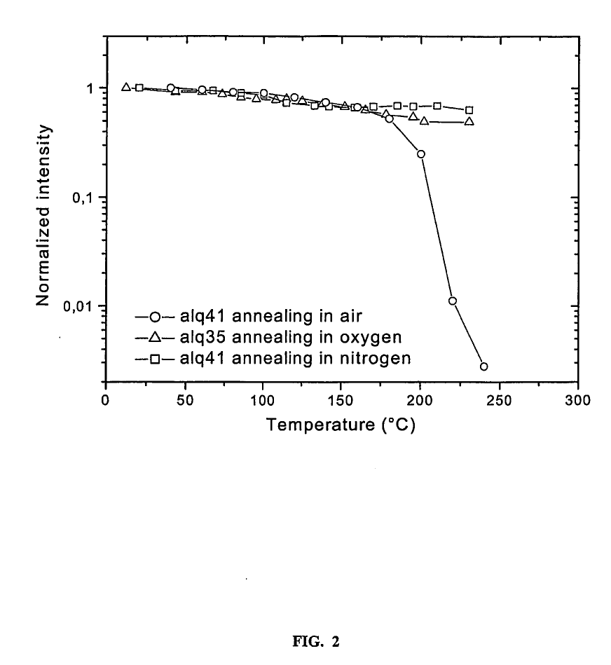

FIG. 2. The figure illustrates the photoluminescence at room temperature of three films of Alq₃ heated (annealed) for 10 min in air, oxygen and nitrogen at the indicated temperature. At the start of the measuring the Alq35 and Alq41 samples were 30 and 130 nm thick, respectively.

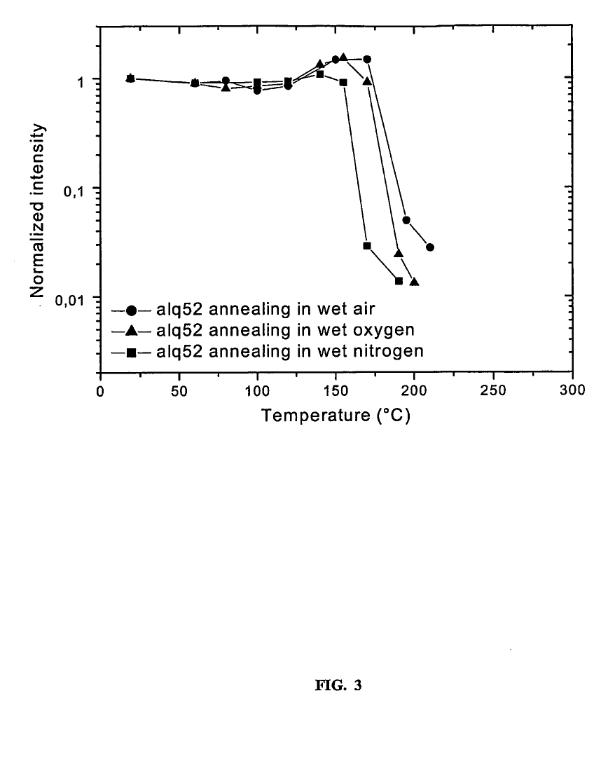

FIG. 3. The figure illustrates the photoluminescence at room temperature of three films of Alq₃ heated (annealed) for 10 min in air, oxygen and nitrogen humidified by water gurgling, at the indicated temperatures. At the start of the measuring the Alq52 samples were 110 nm thick.

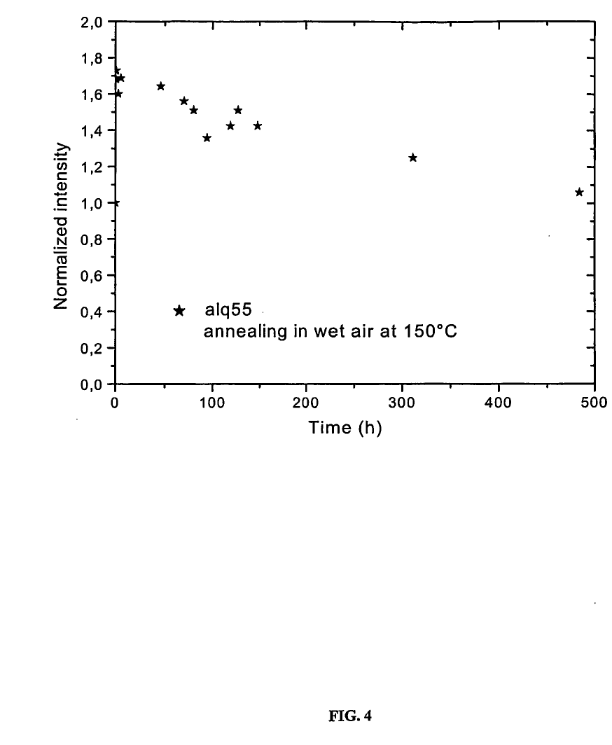

FIG. 4. The figure illustrates the photoluminescence at room temperature of one Alq₃ film measured in air for 500 hours after the heating (annealing) in a humidified atmosphere for 20 min at 150° C. Intensity point 1,0 corresponds to the relative value of the emission just prior to the heating. Prior to the treatment the film was 40 nm thick.

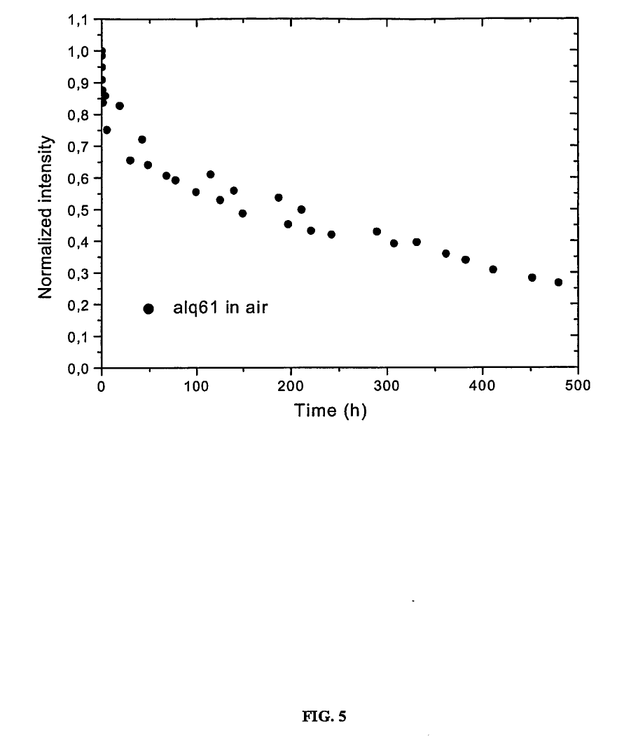

FIG. 5. The figure illustrates the photoluminescence at room temperature of an Alq₃ film measured in air for 500 hours after the evaporation process. The Alq61 sample is 45 nm thick.

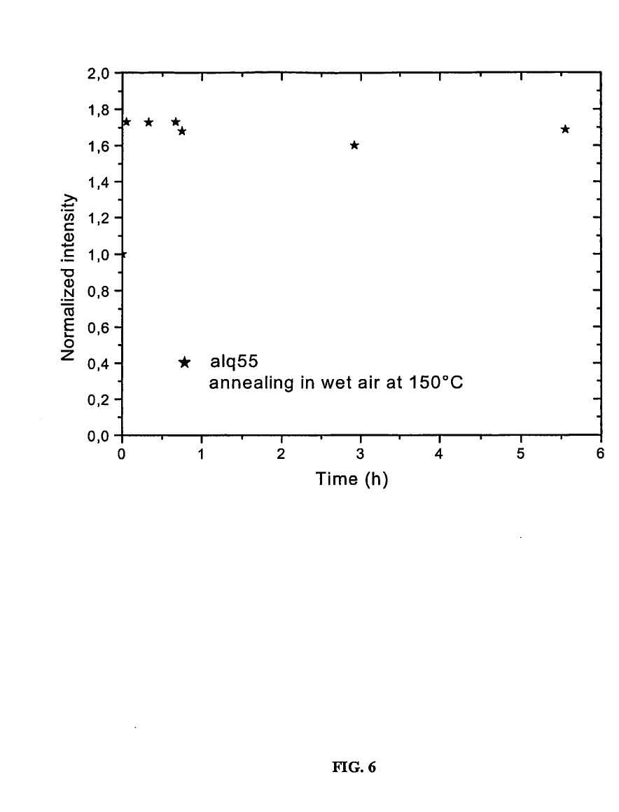

FIG. 6. The figure illustrates the photoluminescence at room temperature of the Alq55 sample measured for the first 6 hours after the heating (annealing) in a humidified atmosphere for 20 min at 150° C. Point 1 corresponds to the relative value of the emission just before the heating. Prior to the treatment the Alq55 sample was 40 nm thick.

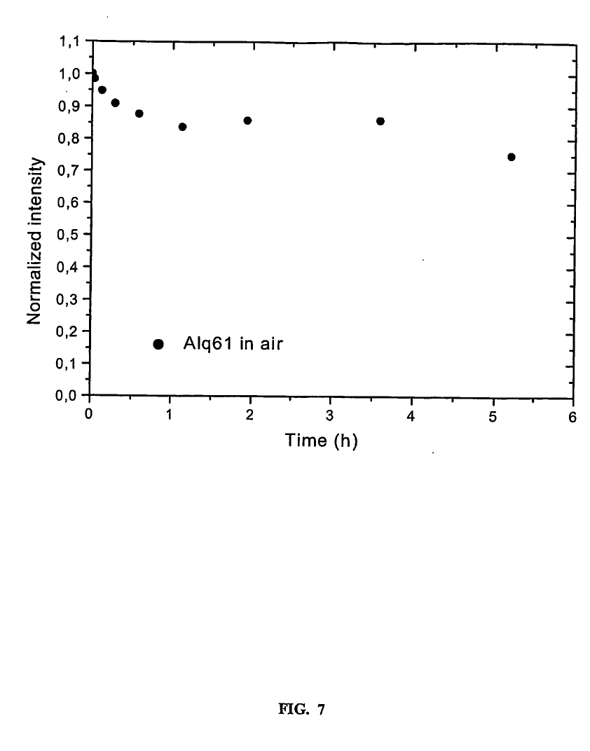

FIG. 7. The figure illustrates the photoluminescence at room temperature of an Alq₃ film measured in air for the first 6 hours after the evaporation process. The Alq61 sample is 45 nm thick.

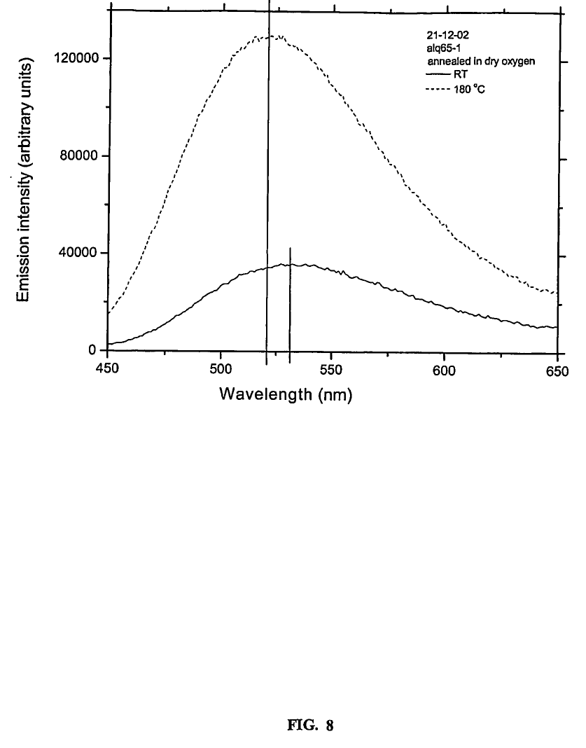

FIG. 8. The figure illustrates emission spectra at room temperature of the Alq65-1 sample before and after annealing in dry oxygen at the indicated temperature. Vertical lines approximately indicate the maxima of the curves. The band at room temperature, RT, refers to the situation before the annealing process.

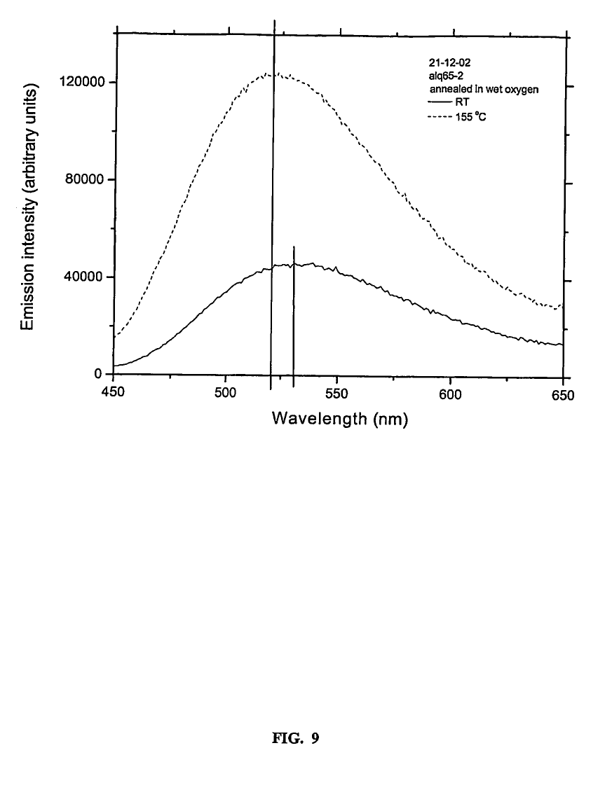

FIG. 9. The figure illustrates emission spectra at room temperature of the Alq65-2 sample before and after annealing in humidified oxygen at the indicated temperature. Vertical lines approximately indicate the maxima of the curves. The band at room temperature, RT, refers to the situation before the annealing process.

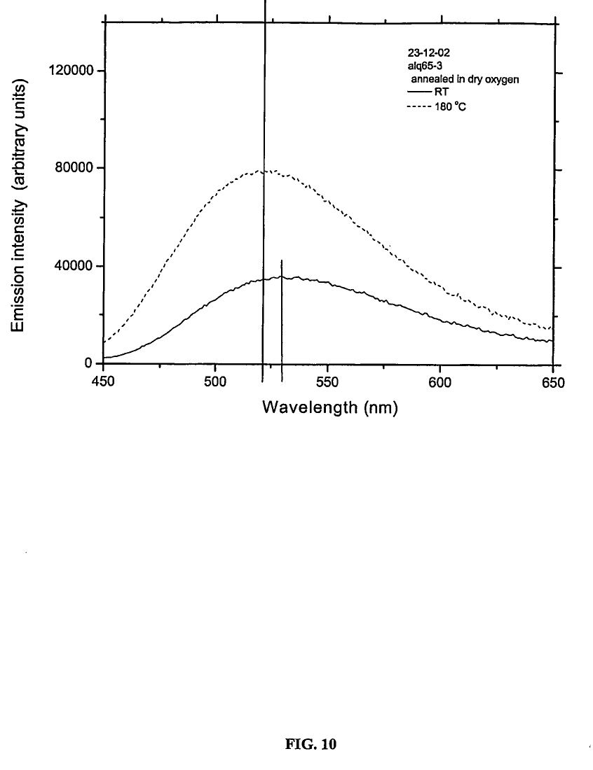

FIG. 10. The figure illustrates emission spectra at room temperature of the Alq65-3 sample before and after annealing in dry nitrogen at the indicated temperature. Vertical lines approximately indicate the maxima of the curves. The band at room temperature, RT, refers to the situation before the annealing process.

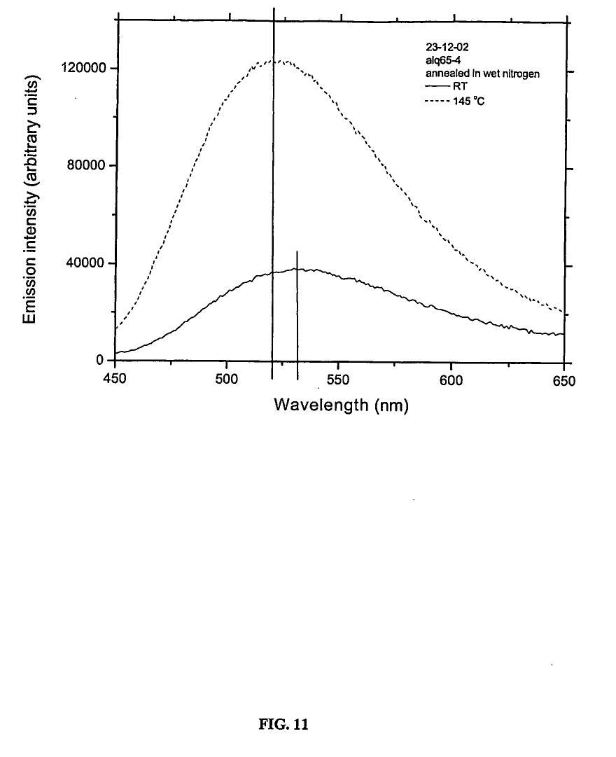

FIG. 11. The figure illustrates emission spectra at room temperature of the Alq65-4 sample before and after annealing in humidified nitrogen at the indicated temperature. Vertical lines approximately indicate the maxima of the curves. The band at room temperature, RT, refers to the situation before the annealing process.

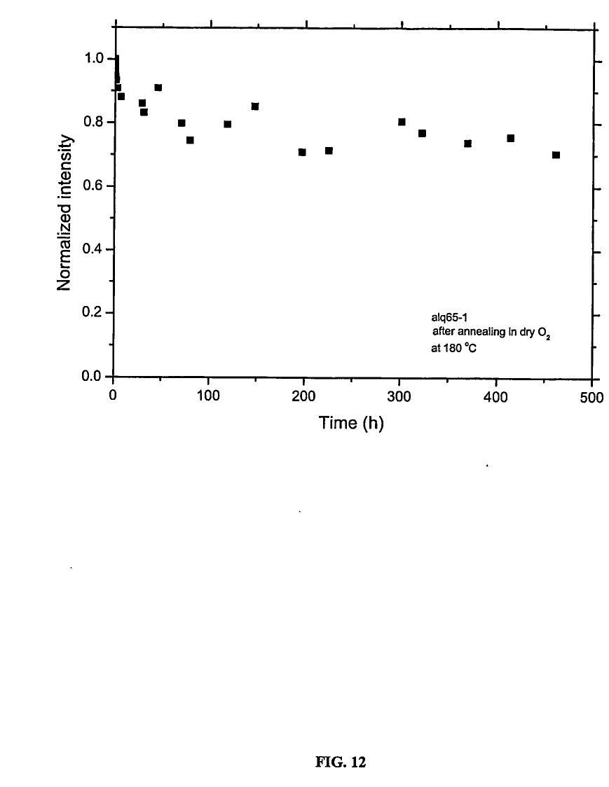

FIG. 12. The figure illustrates the photoluminescence at room temperature of the Alq65-1 sample measured in air for 500 hours after the annealing in dry oxygen for 10 min at 180° C.

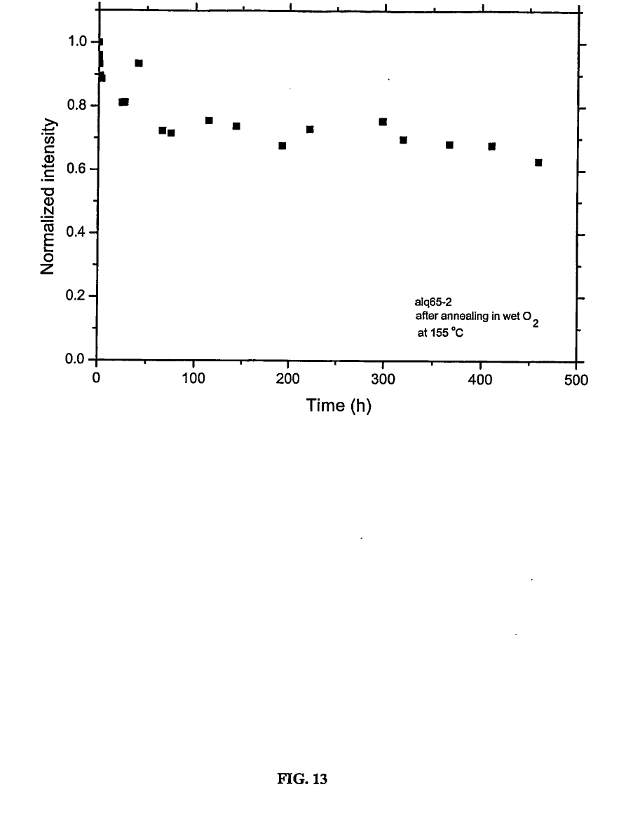

FIG. 13. The figure illustrates the photoluminescence at room temperature of the Alq65-2 sample measured in air for 500 hours after the annealing in humidified oxygen for 10 min at 155° C.

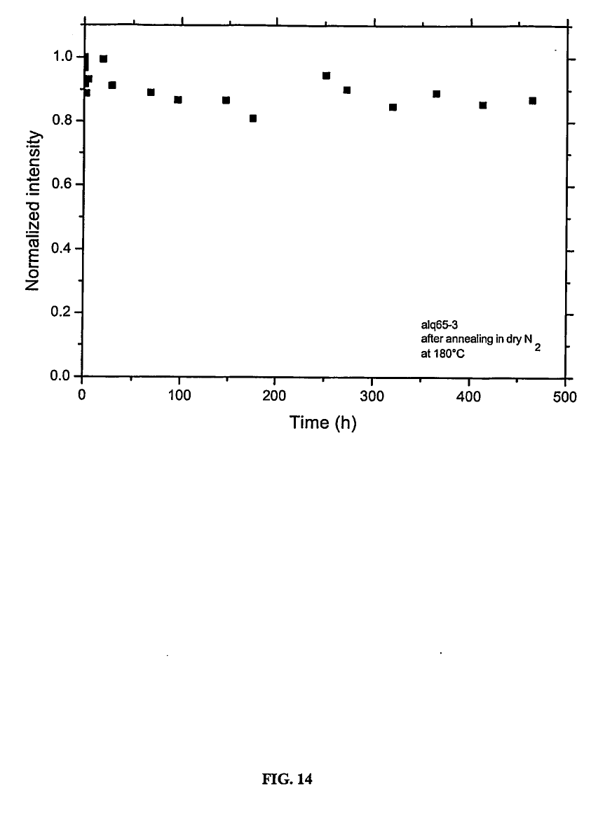

FIG. 14. The figure illustrates the photoluminescence at room temperature of the Alq65-3 sample measured in air for 500 hours after the annealing in dry nitrogen for 10 min at 180° C.

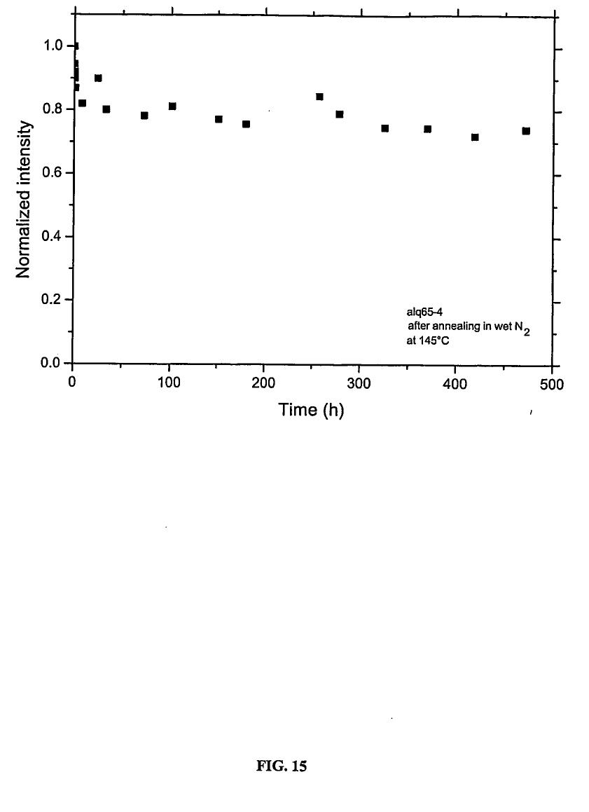

FIG. 15. The figure illustrates the photoluminescence at room temperature of the Alq65-4 sample measured in air for 500 hours after the annealing in humidified nitrogen for 10 min at 145° C.

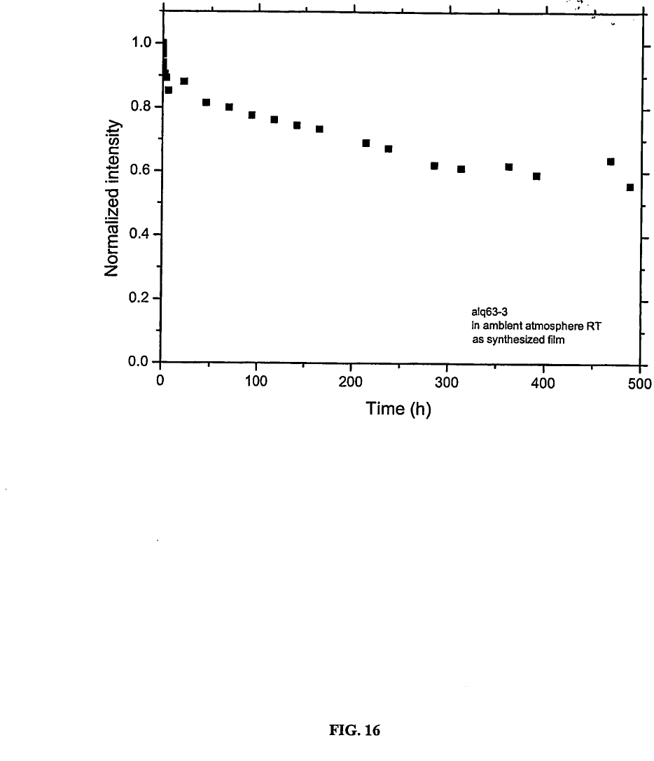

FIG. 16. The figure illustrates the photoluminescence at room temperature of the Alq63-3 sample measured in air for 500 hours right after the evaporation process.

### DETAILED DESCRIPTION

The invention, in a first embodiment thereof, consists in a method of preparing an organic material, deposited in form of a luminescent thin film, having a high emissive power stabilized over time. A second embodiment consists in a method of stabilizing the luminescence of an organic material previously deposited in form of thin film on an inert support. A further embodiment consists of a method of regenerating a film of organic luminescent material that, due to the exposure to deactivating agents, has a luminescent emission too low for a practical application.

The organic luminescent substances in accordance with the present application are photoluminescent, electroluminescent or chemoluminescent substances. Specifically, they are metal chelates of the M(QO)n type, where M is the metal, QO is the hydroxyquinoline and n equals the oxidation state of the metal M. In the preferred embodiment of the invention, the luminescent substance is tris-(8-hydroxyquinoline) aluminum (Alq₃), its derivatives, like the phenoxy-bis-(8-hydroxyquinoline) aluminum (Alq2-OPh), 5,10,15,20-tetraphenyl-21H,23H-porphyne/Alq3 (TPP)/Alq3 complex, or functionally equivalent substances. Alternatively, the organic luminescent substance is replaced by a mixture of two or more of the abovementioned substances, or by a mixture comprising additional substances capable of modulating the color or other aspects of the emission. Examples of such substances are tetracene, anthracene, carbazole, rubrene, TBD, PKV, DMC, α-6T, Er(TTA)₃(phen).

These mixtures can further comprise anti-oxidizing stabilizing substances of phenolic origin exhibiting no absorption bands on the same emission region of the organic luminescent substances. Examples of such phenolic substances are: phenol, vanillin, L-tyrosine, butylated hydroxyanisole (BHA), butylated hydroxytoluene (BHT), vitamin E, propyl gallate, 2,4,6-tri-t-butylphenol, hydroxytyrosol, caffeic acid. The abovementioned substances or their mixtures are used for the preparation of thin luminescent films deposited on suitable solid supports. The deposition method is well known to a person skilled in the art and it consists in a thermal evaporation/sublimation process under vacuum of the pure substances or of mixtures thereof in form of powder. The evaporation process is carried out in molybdenum crucibles overtopped by the solid substrates kept at room temperature and at a distance from the crucible of from 10 to 30 cm, e.g. of 10, 12, 20, 28, 30 cm. The vapors of the organic substance or mixture condense on said substrates forming luminescent material films having thickness of from 10 to 150 nm, preferably of less than 100 nm, in the optimal form from 45 to 55 nm. The material deposited in form of film and obtained with the abovementioned method has, particularly when containing no phenolic stabilizers, a high sensitivity to atmospheric agents. The luminescence of these films, kept in air or other gas atmosphere containing normal moisture rates, decays quickly and progressively with a half-life of a few hours, as it is shown in FIG. 1. Moreover, the decay kinetics of the luminescent emission is markedly influenced by temperature. A 10-min heat treatment in an air atmosphere containing normal moisture rates, i.e. of about the 50%, causes the complete deactivation of the luminescence already below a 250° C. temperature, as it is illustrated in FIG. 2. The Figure shows in a semi-log graph the photoluminescence patterns for three films in air, anhydrous oxygen and anhydrous nitrogen, measured after each heat treatment at increasing temperatures up to 250° C. While anhydrous oxygen and nitrogen do not appear to have substantial effects, though anhydrous oxygen attenuates luminescence more markedly, air containing about 50% moisture completely annihilates the emissive capabilities of the film, whereas the same film is physically destroyed above about 200° C. (FIG. 2).

Accordance to the invention, the luminescent films obtained as above described can be stored in an anhydrous environment for periods even of one year, or subjected, right after their production and optionally after having measured their luminescent power, to a subsequent heat treatment. This treatment, called annealing, is conducted in an atmosphere of air, oxygen, nitrogen, inert gas or mixtures thereof containing more than 50% moisture, preferably more than 60%, 70% or 80%, and still more preferably in a moisture-saturated atmosphere. The optimum moisture level is attained by passage or gurgling of the air or other gas directly in a water bath. The air may be partially or completely replaced by pure oxygen, pure nitrogen or other gas or their mixtures. These treatments can likewise be performed in anhydrous atmospheres.

The heat treatment is performed with any heating means enabling temperature control, like a thermo-regulated oven provided with an inlet for the introduction of the suitable atmosphere. A few minutes of heating, e.g. 5 to 30 min, yet preferably about 10 min, suffice to complete the step of annealing.

Experimental data reported in the present application unexpectedly demonstrated that, while a heat treatment of a mere 10 min at increasing temperature in a low moisture percent (e.g., 50%) atmosphere causes the total decay of the luminescence (FIG. 2), the same treatment in a moisture-rich atmosphere causes, within certain temperature limits, a dramatic increase of the luminescent emission intensity followed, owing to a further temperature increase, by a fast and total decay of the same (FIGS. 3, 9 and 11). An equivalent increase of the emission intensity is attained also operating in an anhydrous atmosphere of oxygen or of nitrogen (FIGS. 8 and 10). Therefore, for each luminescent material used the annealing temperature should be such as to produce said increase in the emission intensity, without anyhow overstepping the threshold resulting in the subsequent deactivation of the luminescence. Hence, a preliminary study as illustrated in FIG. 3 for each luminescent material and/or atmosphere used allows to identify the temperature intervals suitable to attain increases of the intensity of the film luminescence, which increases in the case of Alq₃ amount to a factor from 2 to more than 4 (the maximum value of 4.13 was attained for a film annealed in dry nitrogen). Experimental data demonstrated that when the luminescent material be or mainly contains the Alq₃ molecule this temperature should be held within the range of 150°±30° C., preferably of 140° to 170° C., e.g. at 150° C. when operating in air. Temperatures of from 145° to 180° C. yield optimal results even operating in atmosphere of humidified as well as anhydrous oxygen or nitrogen.

After the step of annealing, the films of fluorescent material thus treated are kept in the same humidified atmosphere for a period of time sufficing to return them to room temperature, in general of some minutes, however no more than 5. Experimental data reported in the examples demonstrate not only that the keeping in humidified air in no way alters the entity of the emission, but also that the luminescence is stabilized for more than 500 hours at the optimum levels reached during the step of annealing, as illustrated by FIGS. 4, 6, 12, 13, 14 and 15. On the contrary, keeping films not heat-treated in the same experimental conditions after their production causes an immediate deactivation down to practically useless emission levels, as illustrated by FIGS. 5, 7 and 16.

What is known from preceding studies at present falls short of conclusively explaining all the results reported in the present application. For example, the luminescence decrease above a certain temperature (FIGS. 2 and 3) may be ascribed to the action of water reacting with Alq₃ to produce 8-Hq, 8-hydroxyquinoline, a product more volatile than Alq₃ that evaporates violently destroying the entire film.

In order to explain the results related to the increase of emission intensity illustrated in FIG. 3, a further series of tests was conducted using freshly-prepared films, obtained as described in the examples. These were subjected solely to one or two heating temperatures, one of which in the range in which the increases in luminescence had previously been measured. Thus, there were eliminated possible positive or negative effects of the subsequent heating performed in the tests illustrated in FIGS. 2 and 3 and any reversibility phenomena due to a less freshly-prepared film.

The new results obtained not only confirmed those previously observed concerning the photoluminescence increase, but highlighted, wholly unexpectedly, that the entity of the increase varies from a factor 2 to more than 4 in the different cases. Moreover they showed that the luminescence band spectrally shifts toward wavelengths in the blue field (FIGS. 8, 9, 10 and 11). This shifting highlights a phase transformation of the luminescent material that can also explain the phenomenon of the increase in the emission intensity.

In fact, it is known that the Alq₃ material can be aggregated in the different crystalline phases α, β, γ, and δ, or C, A and B [M. Coelle, J. Gmeiner, W. Milius, H. Hillebrecht, and W. Brutting, “Thermal and Structural Properties of the Organic Electroluminescent Material Tris(8-hydroxyquinoline)aluminum (Alq₃)” Proc. 11^{th} International Workshop on Inorganic and Organic Electroluminescence, EL 2002, Ghent, Belgium, Sept. 23-26, 2002, pags. 133-136], besides possessing different spectroscopic and morphologic properties. In fact, while the α phase emits light rather shifted in the red spectrum, the δ phase emits lights with wavelength more shifted toward the blue with greater efficiency and more stability to the degradation processes.

Without wishing to bound the invention to theory, in the light of the foregoing we can reasonably suppose that the annealing process transforms part of the α-phase initially present in the film into δ-phase, thereby explaining both the luminescence increase and the shifting to blue. The different absolute values of these variations can depend on several factors, such as the initial morphological composition of the films determined by the evaporation conditions (duration, temperature, distance from the crucible, etc.) as well as on the type of atmosphere in which the annealing process is conducted. The different initial morphological composition of the films can also explain their different behaviour towards degradation, which can be more or less rapid depending on the composition of the phases.

In any case, though with different initial luminescence increases, all of the heated films degrade more slowly than the unheated ones, as they comprise a greater quantity of the δ component that is stabler than the α one.

The results highlighted above are all the more surprising, in view of the fact that a consistent increase of the luminescence and slowing down of the degradation can be achieved already at temperatures in the neighborhood of 150° C., whereas previous experiences indicated that the δ phase was obtained by sublimation and annealing at about 385° C., a temperature far higher and impracticable for films, let alone for completed devices.

The stabilized luminescent material films obtained as described hereto are used for the preparation of devices, called OLEDs, luminescent when suitably excited, e.g. by electric current flow.

The scheme of a typical OLED device is disclosed, e.g., in the preceding Intl. Appln. PCT/IT02/00504 or in literature. Such a scheme foresees a multilayer structure comprising the support, a layer containing the anode, a layer that easily transports holes (also indicated as HTL), a luminescent layer (also indicated as LL), a layer that easily transports electrons (also indicated as ETL) and a layer containing the cathode. Any organization change in the structure of the device is encompassed by the present invention, insofar as the luminescent layer is in accordance therewith.

Optionally, the luminescent devices can be encapsulated in outside atmosphere-proof systems capable of sealing the luminescent material off from contact with atmospheric agents.

The invention is disclosed hereinafter by way of non-limiting examples thereof.

### EXAMPLES 1 TO 7

Different samples of luminescent films were produced by evaporation/sublimation under vacuum of the Alq3 substance and subsequently treated in accordance with the present invention. In this case, the only devices processed consisted of a single layer of luminescent material deposited on a support, or at most of two layers the second one of which having a protective function. The samples made for this study, freshly-prepared or long time-prepared, are reported in Table 1.

TABLE 1

| | | | Sample | |
|---|---|---|---|---|
| | | | keeping | |
| | Thick- | | in the | Annealing |
| | ness | Evaporation | mean- | date and |
| EXAMPLES | (nm) | date | time | atmosphere |
| Example 1: Alq35 | 30 | Jan. 10, 2001 | drier | Jan. 04, 2002 O₂ |
| Example 2: Alq41 | 130 | Feb. 12, 2001 | drier | Dec. 22, 2001 air |
| — | — | — | — | Dec. 24, 2001 N₂ |
| Example 3; Alq52 | 110 | Jan. 10, 2002 | drier | Dec. 12, 2002 |
| | | | | Humidified air |
| — | — | — | — | Jan. 15, 2002 |
| | | | | Humidified N₂ |
| — | — | — | — | Jan. 17, 2002 |
| | | | | Humidified O₂ |
| Example 4: Alq55 | 40 | Jan. 19, 2002 | drier | Jan. 29, 2002 |
| | | | | Humidified air |
| Example 5: Alq60 | 140 | Jan. 05, 2002 | none | Apr. 05, 2002 |
| Example 6: Alq61 | 45 | Apr. 10, 2002 | none | Apr. 10, 2002 |

The Alq₃ substance used in the examples is of commercial origin (Aldrich) as well as freshly-synthesized by means of known methods.

For the preparation of the films there were used microscope glass slides pretreated in a degreasing ultrasonic bath and then with solutions of surfactants, acids, potassium bichromate and alcohols in subsequent steps alternate to rinsings in doubly distilled water and thereafter dried in a flux of nitrogen gas. The deposition of the fluorescent substance in a film was performed by evaporation under vacuum (1.6×10⁻⁶ torr) operating in molybdenum crucibles at a temperature sufficing to cause evaporation/sublimation of the Alq₃ powders, for times of from about 10 minutes to some hours, whereas the support was held above the crucible at a distance of from 10 cm to 30 cm and at room temperature.

The thickness of the films, reported in Table 1, can suitably be controlled both during the growth, by means of a Varian model n. 985-7019 Thickness Monitor, and after the growth, by using a Tencor Alphastep profilometer. Other measuring instruments are available on the market and known to a person skilled in the art. The films thus prepared were dismounted from the evaporation apparatus and stored in a drier at room temperature and in an anhydrous atmosphere prior to being processed in accordance with the invention. The subsequent step of annealing was conducted subjecting the film to a heat treatment for about 10 min, at about 150° C., in a moisture-saturated atmosphere obtained inletting air, pre-passed through a water bath, into the heating apparatus. After this heating step the films were returned to room temperature and kept in the same saturated atmosphere for more than 5 min.

The measurements of the optical adsorption of films treated or untreated in accordance with the invention were performed by using a Perkin-Elmer 119 spectrophotometer. The luminescent emission was measured by using a Jobin-Yvon Fluorolog-3 spectrofluorometer with a front-facing detecting geometry where both the excitation at 395 nm and the luminescence insist from the same side of the thin film with an angle of about 20° between the geometric axes. All measurements were performed in open atmosphere without any permanent protection of the thin film and at room temperature, the performing of each measurement requiring about 5 min. With the exception of the measurement times and of the time required to dismount the just-prepared film from the evaporation apparatus, about 5 min, pending further treatment, all films were kept at room temperature in a dry box. This was meant to avoid any forming of non-luminescent complexes requiring some hours of exposure to the moisture-containing atmosphere in normal laboratory conditions.

The effects of atmosphere on the luminescence of an unprotected film, Alq60, are reported in FIG. 1, both in the case of an atmosphere in a laboratory environment (dark circles) and in that of the same atmosphere in a dry hood (light circles).

In a second experiment, the Alq41 and Alq35 films were heated for 10 min in an atmosphere of anhydrous oxygen, anhydrous nitrogen and air containing ≦50% moisture. The results are reported in FIG. 2. The heating to >150° C. in a low-moisture atmosphere causes the fast and complete deactivation of the luminescent emission.

Other three samples of the Alq52 film were subjected to heat treatment in different moisture saturated atmospheres (about 100% water), precisely in air, oxygen and nitrogen. The results are reported in FIG. 3. The effect of humidity is dramatic, as all three films are completely destroyed at different temperatures, all below about 200° C. Yet, contrarily to what is reported in FIG. 2, prior to the irreversible drop of the luminescence, a substantial increase of the same is observed; in fact, it should be noted that the scale of the intensities is logarithmic.

In a further experiment, the Alq55 film was directly heated for 10 min at 150° C. in a humidified atmosphere with the result of increasing its emission intensity of the 70%, as expected in view of the measurements reported in FIG. 3. After this treatment the sample was returned to room temperature in humidified air in the shortest viable time, and after the first luminescence measurement kept at room temperature in humidified air for 20 min undergoing no emission decrease, then left in open atmosphere for 500 hours, i.e. approximately three weeks. FIG. 4 shows the pattern of the photoluminescence of this sample, having taken the initial value prior to the annealing process as value 1.

By way of comparison, a second sample, the Alq61 film, not subjected to any heat process after the initial evaporation, was kept in open atmosphere like the preceding Alq55 film for the same time. FIG. 5 reports its photoluminescence pattern over time. With respect to the preceding sample subjected to annealing in humidified air, a dramatic drop in intensity is apparent. Yet, even more surprising is the pattern of the luminescence of the two samples compared in the initial hours of the experiment. These patterns are highlighted in FIGS. 6 and 7 that relate to the initial 6 hours of the Alq55 and Alq61 samples. The Alq55 sample, after a luminescent intensity increase of about the 70%, exhibits no apparent drop in the experimental time, contrarily to the Alq61 sample, which immediately exhibits a significant decrease in emission. To this interesting result it should be added that the first 20 min of the Alq55 sample after the annealing process elapsed in a humidified atmosphere undergoing no decay, whereas the same process would have been disastrous for an unheated film.

### EXAMPLES 7 TO 10

In a second series of experiments, new films were produced in accordance with the method described in the preceding examples, but adopting the experimental conditions reported herebelow. The films were generated by evaporation of Alq₃ powder (Aldrich), and for the different evaporations their thickness ranges from 45 to 55 nm. For each evaporation four identical films designated AlqMN-O are produced, in which MN is the sequence number of evaporation, whereas O is 1, 2, 3, 4 indicates one of the four films. All samples were used right after their depositing, or at latest within a few days, having been stored under vacuum or in a dryer. The annealing measurements were performed in different ambient conditions and at optimal temperatures predetermined for each film, as indicated in Table 2, but always for a period of 10 minutes after having attained the thermal and atmospherical balance typical of the individual measurement. The adsorption and the emission with excitation at 395 nm were measured for each sample. Then the optical measurements were carried on in order to study the decay of the various films kept in room atmosphere. The samples generated for this study are reported in Table 2, and the results illustrated by FIGS. 8 to 16.

TABLE 2

| | | | |
|---|---|---|---|
| Example 7 | Alq65-1 | Heating | In dry oxygen |
| | | at 180° C. | |
| Example 8 | Alq65-2 | Heating | In humidified |
| | | at 155° C. | oxygen |
| Example 9 | Alq65-3 | Heating | In dry |
| | | at 180° C. | nitrogen |
| Example 10 | Alq65-4 | Heating | In humidified |
| | | at 145° C. | nitrogen |
| Comparative | Alq63-3 | No Heating | |
| Example 11 | | | |

FIG. 8 shows the emission bands of the Alq65-1 sample before and after the annealing process in dry oxygen. Two quite important details are immediately evident. After the annealing process, the intensity of the band peak increases of a factor of about 3.7 and the wavelength of the maximum shifts into blue of about 12 nm. FIGS. 9, 10 and 11, referring to humidified oxygen, dry nitrogen and humidified nitrogen, respectively, show the same general variations, though with numerical values different thereamong.

FIG. 12 shows the pattern over time in air of the maximum intensity of the emission band of sample Alq65-1 after the annealing process in dry oxygen, monitored for 500 hours. FIGS. 13, 14 and 15 show the same patterns for the other samples, in that order. For a significant comparison, FIG. 16 shows the same pattern for the Alq63-3 sample that has not been subjected to any annealing process, and therefore that can be taken as reference.

The above described results, and many comparable other results obtained in the same test cycle, though not reported here confirm that:

the annealing process at about 150° C. in any type of atmosphere increases of a factor 2 to 4 the intensity of the film photoluminescence (the maximum value of 4.13 was attained for another film annealed in dry nitrogen),

after the annealing process the barycenter of the band shifts consistently toward the blue field of the spectrum.

the films subjected to the annealing process degrade over time more slowly than the freshly-evaporated films, as it is evident from a comparison of the data reported in FIGS. 12, 13, 14 and 15 with those related to the comparative product of FIG. 16,

there are differences among samples showing the existence of processes due to the type of atmosphere used in the annealing.

1. Method of preparing an organic luminescent material comprising the steps of depositing a thin film of organic luminescent substance on a solid inert support, then heat-treating (annealing) the deposited substance at a predetermined temperature in a humidified or anhydrous atmosphere and, finally, returning to room temperature keeping the substance in the same atmosphere.

2. Method according to claim 1, wherein the humidified atmosphere is an atmosphere of oxygen, nitrogen, air, inert gas or mixture thereof, containing more than 50% moisture, or of anhydrous oxygen, nitrogen, or inert gas or mixtures thereof.

3. Method according to claim 2, wherein the annealing is performed at a predetermined temperature ranging from 120° C. to 180° C. for a period of time of 5 to 30 minutes, followed by returning to room temperature in a time not longer than 5 minutes.

4. Method according to claim 3, wherein the predetermined temperature of annealing is the temperature producing the maximum increase of the emission intensity of the film.

5. Method according to claim 4, wherein the organic luminescent substance is a photoluminescent or electroluminescent substance selected from the group consisting of tris-(-8-hydroxyquinoline) aluminum (Alq3), phenoxy-bis-(8-hydroxyquinoline) aluminum (Alq2-OPh), 5,10,15,20-tetraphenyl-21H, 23H-porphine/Alq3 (TPP)/Alq3 complex, functionally equivalent substances and mixtures thereof.

6. Method according to claim 5, wherein the organic luminescent substance optionally comprises one or more substances selected from the group consisting of tetracene, anthracene, carbazole, rubrene, TBD, PKV, DMC, α-6T and Er(TTA)3(phen) and/or one or more phenolic compounds capable of stabilizing luminescence selected from the group consisting of phenol, vanillin, L-tyrosine, butylated hydroxyanisole (BHA), butylated hydroxytoluene (BHT), vitamin E, propyl gallate, 2,4,6-tri-t-butylphenol, hydroxytyrosole, and caffeic acid.

7. Method according to claim 1, wherein the film of organic luminescent substance is generated by evaporating/sublimating under vacuum the luminescent substance and depositing the vapors on an inert flat support of glass, crystal, plastics material or any other substance compatible with adsorption, emission and detection of light.

8. Method according to claim 1, wherein the organic luminescent substance comprises Alq3, the annealing is performed at about 150° C. for about 10 minutes, the humidified atmosphere is water-saturated air and after annealing the film is returned to room temperature in the same atmosphere in a time not longer than 5 minutes.

9. Method of stabilizing the luminescence of an organic photoluminescent or electroluminescent substance comprising annealing the substance at a predetermined temperature in a humidified or anhydrous atmosphere and then returning to room temperature keeping the substance in the same atmosphere.

10. Method according to claim 9, wherein the humidified atmosphere is an atmosphere of oxygen, nitrogen, air, inert gas or mixture thereof containing more than 50% moisture, or the anhydrous atmosphere is an atmosphere of oxygen, nitrogen, inert gas or mixture thereof.

11. Method according to claim 10, wherein the annealing is performed at a predetermined temperature ranging from 120° to 180° C. for a period of time of 5 to 30 minutes, followed by returning to room temperature in a time not longer than 5 minutes.

12. Method according to claim 11, wherein the predetermined temperature of annealing is the temperature producing the maximum increase of the emission intensity of the film.

13. Method according to claim 9, wherein the organic luminescent substance is a photoluminescent or electroluminescent substance selected from the group consisting of tris-(-8-hydroxyquinoline) aluminum (Alq3), phenoxy-bis-(-8-hydroxyquinoline) aluminum (Alq2-OPh), 5,10,15,20-tetraphenyl-21H, 23H-porphine/Alq3 (TPP)/Alq3 complex, functionally equivalent substances and mixtures thereof.

14. Method according to claim 13, wherein the organic luminescent substance optionally comprises one or more substances selected from the group consisting of tetracene, anthracene, carbazole, rubrene, TBD, PKV, DMC, α-6T and Er(TTA)3(phen) and/or one or more phenolic compounds capable of stabilizing luminescence selected from the group consisting of phenol, vanillin, L-tyrosine, BHA, butylated hydroxytoluene (BHT), vitamin E, propyl gallate, 2,4,6-tri-t-butylphenol, hydroxytyrosol, and caffeic acid.

15. Method according to claim 14, wherein the organic luminescent substance subjected to annealing is in form of film deposited on an inert flat support of glass, crystal, plastics material or any other substance compatible with adsorption, emission and detection of light.

16. Method according to claim 9, wherein the organic luminescent substance comprises Alq3, the annealing is performed at about 150° C. for about 10 minutes, the humidified atmosphere is water-saturated air and after annealing the film is returned to room temperature in the same atmosphere in a time not longer than 5 minutes.

17. Organic luminescent material having a stabilized luminescence, obtainable by the method of preparing according to claim 8 and being in a crystalline phase different from that of the original luminescent substance.

18. Organic luminescent material having luminescence stabilized with the method of stabilizing according to claim to 16 and being in a crystalline phase different from that of the original luminescent substance.

19. Film of organic luminescent material according to claim 17, deposited on an inert support.

20. Film of organic luminescent material according to claim 18, deposited on an inert support.

21. Luminescent device comprising the film according to claim 19.

22. Luminescent device comprising the film according to claim 20.

23. Sealed atmospheric agent proof system comprising the device according to claim 21 in an inert atmosphere.

24. Sealed atmospheric agent proof system comprising the device according to claim 22 in an inert atmosphere.

25. Use of device according to claim 21 for the preparation of electrooptic articles.

26. Use of system according to claim 23 for the preparation of electrooptic articles.
